(19) United States
(12) Patent Application Publication
(10) Pub. No.: US 2023/0016663 A1
(43) Pub. Date: Jan. 19, 2023

(54) METHOD FOR DETECTING ABNORMITY, METHOD FOR REPAIRING AND SYSTEM FOR DETECTING ABNORMITY FOR MACHINE SLOT

(71) Applicant: CHANGXIN MEMORY TECHNOLOGIES, INC., Hefei (CN)

(72) Inventor: Shisheng WANG, Hefei (CN)

(73) Assignee: CHANGXIN MEMORY TECHNOLOGIES, INC., Hefei (CN)

(21) Appl. No.: 17/651,604

(22) Filed: Feb. 18, 2022

Related U.S. Application Data
(63) Continuation of application No. PCT/CN2021/117290, filed on Sep. 8, 2021.

(30) Foreign Application Priority Data
Jul. 16, 2021 (CN) 202110807078.4

(51) Int. Cl. G01R 31/26

(52) U.S. Cl. CPC G01R 31/2642; G01R 31/2644

(57) ABSTRACT

A method for detecting abnormity of a machine slot includes the following operations. A first failure rate is obtained. A second failure rate is obtained. A slot, of which the second failure rate is greater than or equal to the abnormity value, is marked as a target slot, and A slot, of which the second failure rate is smaller than the abnormity value, is marked as a control slot. An significance level of a difference between a failure rate of the target slot and a failure rate of the control slot in each day of the second time period is checked.

### CROSS-REFERENCE TO RELATED APPLICATIONS

This is a continuation of International Application No. PCT/CN2021/117290 filed on Sep. 8, 2021, which claims priority to Chinese Patent Application No. 202110807078.4 filed on Jul. 16, 2021. The disclosures of these applications are hereby incorporated by reference in their entirety.

### BACKGROUND

Chips will be tested after being produced in a plant. The chips will be separated and randomly distributed to a plurality of slots of different machines to test. After being tested, each chip will be classified and judged to be a good chip or a failed chip.

Certain problems may be occurred for the test results of the slots while the slots have abnormity. For example, when certain slot has abnormity, the test results of the chips may show that all chips are failed chips. As a result, the slot with the abnormity needs to be tested and repaired so as to improve accuracy of the test results of the chips.

### SUMMARY

Embodiments of the present disclosure relate, but are not limited, to a method for detecting abnormity, a method for repairing and a system for detecting abnormity for a machine slot.

According to an aspect of some embodiments of the present disclosure, a method for detecting abnormity of a machine slot is provided. The machine includes the plurality of the slots and the slots are configured to detect chips. The method for detecting abnormity of a machine slot includes the following operations. A first failure rate is obtained. The first failure rate is a failure rate of chips tested by each slot within a past first time period. An abnormity value is calculated according to all first failure rates. A second failure rate is obtained. The second failure rate is a failure rate of chips tested by the each slot within a past second time period. A duration of the second time period is shorter than a duration of the first time period, and the second time period is within the first time period. A slot, of which the second failure rate is greater than or equal to the abnormity value, is marked as a target slot. A slot, of which the second failure rate is smaller than the abnormity value, is marked as a control slot. An Significance level of a difference between a failure rate of the target slot and a failure rate of the control slot in each day of the second time period is checked.

According to another aspect of some embodiments of the present disclosure, a method for repairing a machine slot is provided. The method includes the following operations. Above significance level is provided, and a target slot is repaired or replaced according to the significance level.

According to another aspect of some embodiments of the present disclosure, a system for detecting abnormity of a machine slot is provided. The system is configured to execute the method for detecting abnormity of the machine slot. The system for detecting abnormity of a machine slot includes a first obtaining module, a calculating module, a second obtaining module and an analyzing module. The first obtaining module is configured to obtain the first failure rate. The calculating module is configured to calculate an abnormity value. The second obtaining module is configured to obtain a second failure rate. The analyzing module is configured to mark a target slot and a control slot, and check a significance level of the target slot.

### BRIEF DESCRIPTION OF THE DRAWINGS

Exemplary description of one or more embodiments is made through pictures in the corresponding drawings thereof, which is not intended to limit the embodiments. Unless specifically stated otherwise, the pictures in the drawings are not limited in proportion.

FIG. 1 is a flowchart showing a method for detecting abnormity of a machine slot provided in an embodiment of the present disclosure.

FIG. 2 is a schematic diagram showing data preparation in a method for detecting abnormity of a machine slot provided in an embodiment of the present disclosure.

FIG. 3 is a functional block diagram showing a system for detecting abnormity of a machine slot provided in another embodiment of the present disclosure.

### DETAILED DESCRIPTION

Errors are liable to occur while a slot with abnormity is tested at present. It is found from analysis that the machine is provided with a plurality of slots and test results may have similar unified characteristics when chips are randomly distributed to different slots to test. At present, an engineer may mainly find a slot with greater yield difference by randomly selecting some chips from each slot and observing sizes of test yields of the chips, and the slot is considered as the slot with the abnormity. For the sampled data, an analyzing process is simpler while true results cannot be completely displayed, and there are certain errors. In addition, it is difficult to display a condition of testing the chips tested by slots due to too single data observation. For example, trend of the failure rate of the chips tested by each slot and time cannot be seen.

To solve the problems, the embodiments of the present disclosure provide a method for detecting abnormity of a machine slot. The method includes the following operations. A first failure rate is obtained. The first failure rate is a failure rate of chips tested by each slot within a past first time period. An abnormity value is calculated according to all first failure rates. A second failure rate is obtained. The second failure rate is a failure rate of chips tested by the each slot within a past second time period. A slot, of which the second failure rate is greater than or equal to the abnormity value, is marked as a target slot. A slot, of which the second failure rate is smaller than the abnormity value, is marked as a control slot. An significance level of difference between a failure rate of the target slot and a failure rate of the control slot in each day within the second time period is checked. In other words, in the embodiment of the present disclosure, the failure rates of the chips tested by all slots within the first time period are obtained, and data volume is relatively sufficient, so that accuracy of obtaining the abnormity value can be improved, the significance level of difference between the failure rate of the target slot and the failure rate of the control slot is compared to further deeply analyze the target slot, such that detection errors are reduced. In addition, the failure rates of the chips tested by the slots within different time periods are obtained, such that the trend of the failure rate of the chips tested by each slot and the time can be conveniently displayed.

The technical solutions provided by the embodiments of the present disclosure at least have the following advantages.

The first failure rate is obtained, and the first failure rate is the failure rate of the chips tested by each slot within the past first time period. In other words, compared with sampling analysis, the data obtained in the embodiments of the present disclosure are test data of all slots, such that integrity and correctness of the data can be ensured. The abnormity value is calculated according to all first failure rates, the second failure rate is obtained, and the control slot and the target slot are marked according to a size relationship between the second failure rate and the abnormity value. In such a manner, the target slot with the abnormity can be directly found. The significance level of the difference between the target slot and the control slot is checked. In such a manner, accuracy of detecting the target slot with the abnormity can be further improved.

In order to make the purpose, technical solutions and advantages of the embodiments of the present disclosure clearer, the embodiments of the present disclosure will be further illustrated in detail in combination with accompanying drawings hereinafter. However, those ordinary skilled in the art can understand that many technical details are provided in the embodiments of the present disclosure to give the reader a fuller understanding of the present disclosure. The technical solution claimed by the present disclosure also may be implemented, even without the technical details and various changes and modifications based on the following embodiments.

As used herein, singular forms “a/an”, “one”, and “the” may include the plural forms, unless otherwise specified types in the context. It is also to be understood that, terms such as “comprising/containing” or “having” appoint existence of declarative features, wholes, steps, operations, components, parts or combinations of them, but not excluding the possibility of existence or adding of one or more other features, wholes, steps, operations, components, parts or combinations of them. Meanwhile, in the specification, term “and/or” includes any and all combinations of the related listed items.

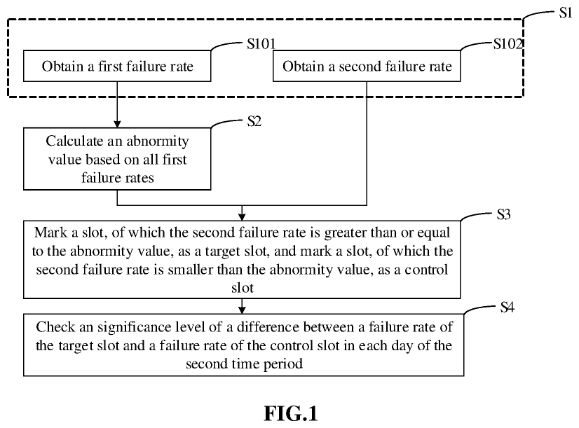

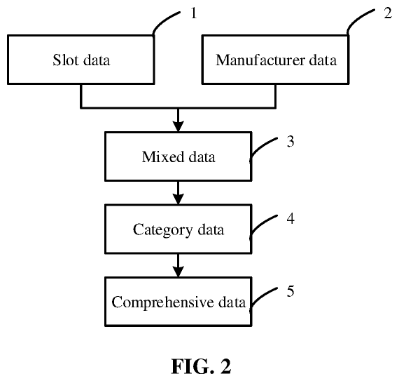

An embodiment of the present disclosure provides a method for detecting abnormity of machine slot. FIG. 1 is a flowchart showing a method for detecting abnormity of a machine slot provided in an embodiment of the present disclosure. FIG. 2 is a schematic diagram showing data preparation in a method for detecting abnormity of a machine slot provided in an embodiment of the present disclosure. The following will provide a specific description in conjunction with the accompanying figures.

Firstly, it should be noted that the machine in the embodiments of the present disclosure is a test machine used in a final test. In some embodiments, one machine is provided with 48 slots which are configured to test a yield of the chips. The chips in the embodiments of the present disclosure may be a die of a wafer. The machine, the slots and the chips are only schematically illustrated above, and are not limited by the embodiments of the present disclosure.

Refer to FIG. 1, in step S1, step S101 and step S102 are included. At step S101, a first failure rate is obtained. At S102, a second failure rate is obtained. The first failure rate is a failure rate of the chips tested by each slot within a past first time period, and the second failure rate is a failure rate of the chips tested by the each slot within a past second time period.

The failure rate is a ratio of number of failed chips tested within certain time period to total number of tested chips. The yield is a ratio of a number of good chips tested within certain time period to total number of tested chips. That is, the sum of the yield and the failure rate is equal to 100%. It should be noted that the failure rate and the yield both involved in the embodiment of the present disclosure are the failure rate and the yield of the chips tested by the slot, rather than the failure rate or the yield of the slot.

In the embodiments of the present disclosure, the operation of obtaining the first failure rate includes the following operations. The yield of the chips tested by the each slot within the first time period is obtained. The first failure rate is calculated according to the yield of the chips tested by the each slot within the first time period. That is, the first failure rate may be calculated through a formula: the first failure rate=100%−the yield of the chips tested by the each slot within the first time period. Similarly, the operation of obtaining the second failure rate includes the following operations. The yield of chips tested by each slot within the second time period is obtained. The second failure rate is calculated according to the yield of the chips tested by the each slot within the second time period. That is, the second failure rate may be calculated through a formula: the second failure rate=100%−the yield of the chips tested by the each slot within the second time period. In other embodiments, the failure rate may be not calculated according to the yield, but is directly obtained.

The duration of the second time period is shorter than the duration of the first time period, and the second time period is within the first time period. In the embodiments of the present disclosure, the second time period is the time period closest to the present in the first time period. That is, the second time period at least includes yesterday. When the second time period is the time period closet to the present, the latest condition of the target slot can be obtained, which is favorable for improving precision of subsequently repairing the target slot with the abnormity.

In some embodiments, the ratio of duration of the first time period to duration of the second time period is from 3:1 to 2:1. The first failure rate within the first time period is used for subsequently calculating an abnormity value, therefore, data volume for calculating the abnormity value is relatively sufficient when the duration of the first time period is long, which is favorable for improving accuracy of finally tested significance level. When the ratio of the duration of the first time period to the duration of the second time period is kept within the range, accuracy of testing can be effectively improved, and complexity level of data processing also can be reduced to certain extent. For example, the past first time period may be the past seven days, and the past second time period may be the past three days. In another embodiments, the past first time period also may be the past six days, eight days or nine days, and the like, and the past second time period also may be the past two days, four days or five days, and the like.

In some embodiments, the step S1 includes three stages of load data, filter data and summary data. That is, the step S1 is an initial data processing stage at which the first failure rate and the second failure rate are obtained.

At a first stage, load data refers to establishing connection with a database to accomplish data preparation work. Refer to FIG. 2, a data preparation process mainly includes the following steps. Firstly, slot data 1 and manufacturer data 2 are obtained, and the slot data 1 may include batch data, machine data, wafer data, test programs, and the like. The slot data 1 and the manufacturer data 2 are performed with statistical processing to obtain mixed data 3. Whether each chip is a normal chip or a failed chip is determined according to the mixed data 3, such that categorical data 4 of the chips are obtained. It should be noted that parameters for determining chip categories under different test programs are different. The failure rate of the chips tested by each slot in each day is obtained according to the above categorical data 4 of the chips, and comprehensive data 5 include the firstly obtained slot data 1, the manufacturer data 2 and the failure rate obtained in the intermediate process.

At a second stage, the filter stage refers to filtering the machine having test data at the past first time period and the past second time period according to the comprehensive data 5.

At a third stage, the summary stage refers to obtaining the failure rate of the chips tested by each slot within the past first time period and the failure rate of the chips tested by each slot within the past second time period. That is, the first failure rate and the second failure rate are obtained.

In some embodiments, after obtaining the first failure rate and the second failure rate, the method further includes the following operations. The slots under the same test program of the same machine are listed as a combination, the first failure rates under the same combination are performed with statistical processing, and the second failure rates under the same combination are performed with statistical processing. That is, the first failure rates and the second failure rates are performed with statistical processing under the same machine and the same test program.

It should be noted that one machine will execute different test programs which are methods for testing the chips. As a result, there is certain difference in the test data under different machines or different test programs. The data are performed with statistical processing through different combinations to favorably compare data subsequently in the same combination, thereby avoiding difference of data in different combinations and improving accuracy of testing the slot with the abnormity.

In some embodiments, the slots under all test programs of the same machine also may be listed as a combination. That is, the first failure rates and the second failure rates of the same machine are performed with statistical processing. Optionally, the first failure rates and the second failure rates also may be performed with statistical processing in a non-group mode.

Continuously refer to FIG. 1, in step S2, an abnormity value is calculated according to all first failure rates.

It should be noted that the abnormity value is an upper limit value in a box-plot, and the result of distinguishing the abnormity value by the box-plot is relatively objective and the box-plot can reflect characteristics of first failure rate distribution. A formula for calculating the abnormity value is as follows: upp_limit=Q₃+1.5IQR. Where, the upp_limit is the abnormity value, the Q₃ is an upper quantile in all first failure rates, and the IQR is a difference value between the upper quantile and a lower quantile in the all first failure rates.

In some embodiments, the abnormity value is obtained according to the first failure rates under the same combination. That is, the all first failure rates are the first failure rates of the chips tested by all slots under the same machine and the same test program. Therefore, the obtained abnormity values also are grouped based on different machines and different test programs. In some other embodiments, the all first failure rates also may be the first failure rates of chips tested by the all slots under all test programs of the same machine. Correspondingly, the obtained abnormity values also may be grouped through different machines. Optionally, in some other embodiments, the data also may be performed with statistical processing in a non-group mode. Therefore, the all first failure rates are the first failure rates under all machines and all test programs. Correspondingly, an independent abnormity value can be obtained.

In step S3, a slot, of which the second failure rate is greater than or equal to the abnormity value, is marked as a target slot, and a slot, the second failure rate of which is smaller than the abnormity value is marked as a control slot.

It should be noted that the second failure rate of certain slot being greater than or equal to the abnormity value means that the failure rate of the chips tested by the slot is great within the past second time period. Therefore, the slot possibly has abnormity, and a test condition in each day of the past second time period of the slot needs to further be analyzed. The second failure rate of certain slot being smaller than the abnormity value means that the failure rate of the chips tested by the slot is relatively small within the past second time period. Therefore, the slot has higher test precision and belongs to a normal slot.

In some embodiments, the target slot and the control slot may be respectively marked to be conveniently compared subsequently.

In step S4, an significance level of difference between a failure rate of the target slot and a failure rate of the control slot in each day of the second time period is checked.

The significance level is checked to favorably learn the size of the difference between the target slot and the control slot. If the degree of significance of the difference is higher, it means that the target slot is more likely to have problems, such that repairing is performed subsequently according to the significance level and accuracy can be further improved.

In some embodiments, the significance levels of all target slots are performed with statistical processing in a combination mode. That is, the significance levels of the target slots under the same test program of the same machine are performed with statistical processing. In some other embodiments, the significance levels of all target slots under all test programs of the same machine further may be performed with statistical processing. Optionally, in some other embodiments, the significance levels of the target slots also may be performed with statistical processing in a non-combination mode.

The following will provide a detailed description of the method for checking the significance level.

Whether the difference between the failure rate of the target slot and the failure rate of the control slot in each day of the second time period is significant is judged. If the difference is significant, a significant mark is set for the target slot.

In some embodiment, the t test method may be adopted to judge whether difference between the target slot and the control slot is significant. Specifically, t test adopts two formulas:

$$t = \frac{\overline{X} - {μ}_{0}}{\frac{s}{\sqrt{n}}} and V = n - 1 .$$

Where, t is configured to compare with a value corresponding to a standard statistical table to judge whether difference is significant, X is a mean value of failure rates of all batches of the chips tested by the control slot within certain day, μ0 is a mean value of failure rates of all batches of the chips tested by the target slot within the same day, s is standard deviation of the failure rates of all batches of the chips tested by the control slot, n is a number of batches of the chips tested by the control slot, and V is degree of freedom. It should be noted that there are a plurality of control slots in the embodiments of the present disclosure. Therefore, X, s and n are average of all control slots. Optionally, one control slot may be selected from the plurality of the control slots to calculate.

The significance level is selected before t is compared with the value corresponding to the standard statistical table. The significance level is generally selected from 0.05, 0.01 and 0.1. The significance level is a predetermined allowable small probability standard which is taken as judgment limit during a statistical test. The smaller the selected value, the stricter the test. Searching is performed in the standard statistical table through the calculated degree of freedom and the significance level to find a contrast value corresponding to t. When |t| is greater than the contrast value in the standard statistical table, it is considered to be that the difference of target slot is significantly higher than the difference of control slot.

In one example, if certain target slot has significant difference in certain day among the past three days, the target slot may be set with a significant mark on this day. For example, the significant mark can be set to be a letter D. It should be noted that the embodiments of the present disclosure do not limit the specific form of the significant mark.

The significant mark of the target slot within the second time period is performed with statistical processing. That is, the number of all significant marks set for the target slot within the second time period is performed with statistical processing. Specifically, in the second time period, the number of days in which the target slot is significant in difference is increased, and the coefficient of the significant mark of the target slot is also increased. In one example, if certain target slot is significant in difference on the latest day, the coefficient of the statistical processed significant mark is 1, if certain target slot is significant in difference within latest two days, the coefficient of the statistical processed significant mark is 2, and if certain target slot is significant in difference within latest three days, the coefficient of the statistical processed significant mark is 3. In other embodiments, the significant condition within different days also may be represented by changing the category of the significant mark.

It should be understood that if the target slot is set with the significant mark, there is relatively great difference between the target slot and the control slot, and the target slot is possibly a slot with problems. As a result, in the embodiment of the present disclosure, the target slot with the significant mark is taken as a slot with abnormity, and an engineer will subsequently analyze the slot with the abnormity deeply to accomplish repair work. In other embodiments, a threshold range of the significant mark also may be set. When the significant mark within the second time period of certain control slot exceeds the threshold range, the control slot is taken as the slot with the abnormity.

Each slot is labeled based on the above statistical processed significant marks. If certain target slot is significant in difference on the latest day, the target slot is labeled with 1D, if certain target slot is significant in difference within latest two days, the target slot is labeled with 2D, if certain target slot is significant in difference within latest three days, the target slot is labeled with 3D, and if certain target slot is significant in difference in one day among the past three days, the target slot is labeled with D. If the control slot is insignificant in difference within the past second time period, the target slot is labeled with N. If a slot does not have data, the slot is labeled with NA to represent a null value. As the label is more visual, the engineer can quickly find the slot with the abnormity.

In some embodiments, the method for detecting abnormity of the machine slot further includes the following operation. A parameter of testing chips within the first time period by the target slot set with the significant mark is obtained. The parameter of testing chips within the first time period may be the failure rate, the yield, the test parameter and the like in each day of the first time period. In such a manner, a specific condition of the test within the past first time period can be conveniently displayed subsequently, and the cause of the problem of the slot with the abnormity is judged.

In some embodiments, the method for detecting abnormity of the machine slot further includes the following operations. The manufacturer data corresponding to each machine is obtained. The manufacturer data of the machine to which the target slot with the significant mark belongs are screened out. In such a manner, the slot set with the abnormity can be conveniently traced to improve efficiency in a subsequent repair process.

In some embodiments, the method for detecting abnormity of the machine slot further includes the following operations. A visual result of the significance levels is generated and a report is generated. The visual result and the report can visually display the specific condition of each slot, which is favorable for improving analyzing efficiency. In addition, the visual result further includes parameters and a yield condition of the chips tested within the past first time period. Further, a schedule further may be set for storing everyday statistical data at regular time, such that the generated report can be sent to the engineer at fixed time.

In conclusion, in the embodiments of the present disclosure, test data of each slot within the first time period is obtained, such that data analysis is convenient and accuracy of data result is improved. In addition, whether each slot has abnormity and the significance level of the abnormity further can be checked, and the trend of the failure rate and the time further can be checked. In such a manner, multi-dimensional data display can be performed to reduce error of detecting the slot with the abnormity.

Another embodiment of the disclosure provides a method for repairing a machine slot. The method includes the following operations. The significance level in the previous embodiment is provided, and the target slot is repaired or replaced based on the significance level.

It can be learned from the above that the target slot set with significant difference possibly has problems. As a result, the accuracy of testing the chips subsequently can be improved after the target slot is repaired based on the significance level.

In some embodiments, before repairing or replacing the target slot, the method further includes the following operations. The cause of the significant difference of the target slot is analyzed according to the parameter of testing chips by the target slot set with the significant mark within the first time period. By analyzing the cause of the significant difference, a subsequent repair rate is favorably increased.

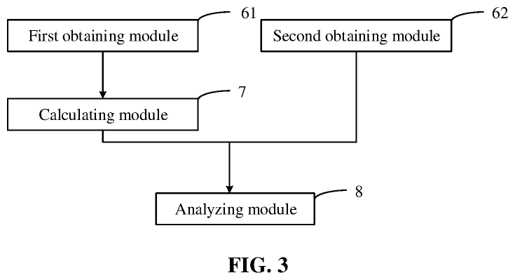

Another embodiment of the present disclosure provides a system for detecting abnormity of a machine slot. The system for detecting abnormity of a machine slot is configured to execute the above method for detecting abnormity of a machine slot in the embodiments. FIG. 3 is a functional block diagram showing a system for detecting abnormity of a machine slot provided in another embodiment of the present disclosure. Refer to FIG. 3, the system for detecting abnormity of a machine slot includes a first obtaining module 61, a calculating module 7, a second obtaining module 62 and an analyzing module 9. The first obtaining module 61 is configured to obtain a first failure rate. The calculating module 7 is configured to calculate the abnormity value. The second obtaining module 62 is configured to obtain the second failure rate. The analyzing module 9 is configured to mark a target slot and a control slot, and check an significance level of the target slot.

In the embodiments of the present disclosure, the system is constructed and operated through a server. For example, the system comprises the server and the machines for testing. The server includes at least one processor and a memory in communication connection with the processor. The memory is configured to store instructions executable for the processor, and the processor is configured to perform the corresponding instructions.

In the embodiments of the present disclosure, chips will be tested after being produced in a plant. The chips will be separated and randomly distributed to a plurality of slots of different machines to test. The test results of the chips will be stored in the database of the machines. The server is connected to the machines and may acquire the data (for example, the first failure rate or the second failure rate) from the machines for analyizing.

It should be understood by those of ordinary skill in the art that the implementation manners are specific embodiments of the present disclosure, and various changes can be made in forms and details in practical application, without departing from the spirit and scope of the present disclosure. Modifications and changes may be made by anyone skilled in the art without departing from the spirit and scope of the present disclosure, and therefore, the protection scope of the present disclosure is subject to the protection scope in claims.

What is claimed is:

1. A method for detecting abnormity of a machine slot, performed by a system for detecting abnormity of the machine slot, wherein a machine comprises a plurality of slots and the plurality of slots are configured to detect chips, and the method comprises:
obtaining a first failure rate, wherein the first failure rate is a failure rate of the chips tested by each slot within a past first time period;
calculating an abnormity value according to all first failure rates;
obtaining a second failure rate, wherein the second failure rate is a failure rate of the chips tested by the each slot within a past second time period, a duration of the second time period is shorter than a duration of the first time period and the second time period is within the first time period;
marking a slot, of which the second failure rate is greater than or equal to the abnormity value, as a target slot;
marking a slot, of which the second failure rate is smaller than the abnormity value, as a control slot;
checking an significance level of a difference between a failure rate of the target slot and a failure rate of the control slot in each day of the second time period; and
determining whether the target slot is abnormal according to the significance level.

2. The method for detecting abnormity of a machine slot of claim 1, wherein obtaining the first failure rate comprises:
obtaining a yield of the chips tested by the each slot within the first time period; and
calculating the first failure rate according to the yield of the chips tested by the each slot within the first time period;
wherein obtaining the second failure rate comprises:
obtaining a yield of the chips tested by the each slot within the second time period, and
calculating the second failure rate according to the yield of the chips tested by the each slot within the second time period.

3. The method for detecting abnormity of a machine slot of claim 1, comprising:
listing the plurality of slots under all test programs of a same machine as a combination;
performed statistical processing on the all first failure rates under a same combination;
obtaining the abnormity value according to the all first failure rates under the same combination;
performed statistical processing on all second failure rate under the same combination; and
performed statistical processing on significance levels of all target slots under the same combination.

4. The method for detecting abnormity of a machine slot of claim 1, comprising:
listing the plurality of slots under a same test program of a same machine as a combination;
performed statistical processing on the all first failure rates under a same combination;
obtaining the abnormity value according to the all first failure rates under the same combination;
performed statistical processing on all second failure rate under the same combination; and
performed statistical processing on significance levels of all target slots under the same combination.

5. The method for detecting abnormity of a machine slot of claim 1, wherein checking the significance level comprises:
judging whether the difference between the failure rate of the target slot and the failure rate of the control slot in each day of the second time period is significant; and
if the difference is significant, setting a significant mark for the target slot.

6. The method for detecting abnormity of a machine slot of claim 5, further comprising:
performed statistical processing on a significant mark of the target slot within the second time period.

7. The method for detecting abnormity of a machine slot of claim 6, wherein performed statistical processing on the significant mark of the target slot within the second time period specifically comprises:
in the second time period, if a number of days in which the target slot is significant in the difference is increased, increasing a coefficient of the significant mark of the target slot.

8. The method for detecting abnormity of a machine slot of claim 5, further comprising:
obtaining a parameter of the chips tested within the first time period by the target slot set with the significant mark.

9. The method for detecting abnormity of a machine slot of claim 5, further comprising:
obtaining manufacturer data corresponding to each machine; and
screening out manufacturer data of a machine to which the target slot set with the significant mark belongs.

10. The method for detecting abnormity of a machine slot of claim 1, wherein a ratio of the duration of the first time period to the duration of the second time period is from 3:1 to 2:1.

11. The method for detecting abnormity of a machine slot of claim 1, further comprising:
generating a visual result of significance levels; and
generating a report.

12. The method for detecting abnormity of a machine slot of claim 1, wherein a formula for calculating the abnormity value is: upp_limit=Q₃+1.5IQR, wherein the upp_limit is the abnormity value, the Q₃ is an upper quantile in the all first failure rates, and the IQR is a difference value between the upper quantile and a lower quantile of the all first failure rates.

13. The method for detecting abnormity of a machine slot of claim 1, wherein steps of obtaining the first failure rate and the second failure rate comprise three stages of load data, filter data and summary data.

14. A system for detecting abnormity of a machine slot, wherein the system comprises a server, the server comprises at least one processor and a memory in communication connection with the processor, the memory is configured to store instructions executable for the processor, and when the instructions are executed by the processor, the processor is caused to perform following operations:
obtaining a first failure rate, wherein the first failure rate is a failure rate of the chips tested by each slot within a past first time period;
calculating an abnormity value according to all first failure rates;
obtaining a second failure rate, wherein the second failure rate is a failure rate of the chips tested by the each slot within a past second time period, a duration of the second time period is shorter than a duration of the first time period and the second time period is within the first time period;
marking a slot, of which the second failure rate is greater than or equal to the abnormity value, as a target slot;
marking a slot, of which the second failure rate is smaller than the abnormity value, as a control slot;
checking a significance level of a difference between a failure rate of the target slot and a failure rate of the control slot in each day of the second time period; and
determining whether the target slot is abnormal according to the significance level.

15. The system for detecting abnormity of a machine slot of claim 14, wherein obtaining the first failure rate comprises:
obtaining a yield of the chips tested by the each slot within the first time period; and
calculating the first failure rate according to the yield of the chips tested by the each slot within the first time period;
wherein obtaining the second failure rate comprises:
obtaining a yield of the chips tested by the each slot within the second time period, and
calculating the second failure rate according to the yield of the chips tested by the each slot within the second time period.

16. The system for detecting abnormity of a machine slot of claim 14, wherein the operations further comprise:
listing the plurality of slots under all test programs of a same machine as a combination;
performed statistical processing on the all first failure rates under a same combination;
obtaining the abnormity value according to the all first failure rates under the same combination;
performed statistical processing on all second failure rate under the same combination; and
performed statistical processing on significance levels of all target slots under the same combination.

17. The system for detecting abnormity of a machine slot of claim 14, wherein the operations further comprise:
listing the plurality of slots under a same test program of a same machine as a combination;
performed statistical processing on the all first failure rates under a same combination;
obtaining the abnormity value according to the all first failure rates under the same combination;
performed statistical processing on all second failure rate under the same combination; and
performed statistical processing on significance levels of all target slots under the same combination.

18. The system for detecting abnormity of a machine slot of claim 14, wherein checking the significance level comprises:
judging whether the difference between the failure rate of the target slot and the failure rate of the control slot in each day of the second time period is significant; and
if the difference is significant, setting a significant mark for the target slot.

19. The system for detecting abnormity of a machine slot of claim 18, wherein the operations further comprise:
performed statistical processing on a significant mark of the target slot within the second time period.

20. The system for detecting abnormity of a machine slot of claim 19, wherein performed statistical processing on the significant mark of the target slot within the second time period specifically comprises:
in the second time period, if a number of days in which the target slot is significant in the difference is increased, increasing a coefficient of the significant mark of the target slot.
